(19) United States
(12) Patent Application Publication
(10) Pub. No.: US 2023/0378102 A1
(43) Pub. Date: Nov. 23, 2023

(54) Switch Arrangement

(71) Applicant: Solaredge Technologies Ltd., Herzeliya (IL)

(72) Inventor: Meir Gazit, Ashkelon (IL)

(21) Appl. No.: 18/320,703

(22) Filed: May 19, 2023

Related U.S. Application Data
(60) Provisional application No. 63/344,348, filed on May 20, 2022.

(51) Int. Cl. H01L 23/64; H01L 25/07

(52) U.S. Cl. CPC H01L 23/642; H01L 25/072

(57) ABSTRACT

An integrated power switch and a method of operating such a switch is disclosed. The integrated power switch may include a source, one or more first drains, and one or more second drains formed on a semi-conductive substrate. Channels may be formed between the source and the plurality of first and second drains. The integrated power switch may further include one or more gates coupled to the first and second channels. Capacitance may be formed by the spatial proximity of the first and second channels, and as a result, a loop inductance may be reduced.

### CROSS-REFERENCE TO RELATED APPLICATIONS

The present application claims priority to U.S. Provisional Application 63/344,348 filed May 20, 2022. The entire disclosure of the foregoing application is incorporated by reference in its entirety.

### BACKGROUND

When designing switching circuits (e.g., power converters), parasitic loop inductance may be an important design parameter. High loop inductance may result in large voltage spikes during switch commutation, potentially resulting in increased switching loss and/or breakdown of a switch. There is a need for switching devices with a reduced loop inductance.

### SUMMARY

The following is a short summary of some of the inventive concepts for illustrative purposes only and is not an extensive overview, and is not intended to identify key or critical elements or to limit or constrain the inventions and examples in the detailed description. One skilled in the art will recognize other novel combinations and features from the detailed description.

Described herein are methods, devices, and systems for providing an integrated switch device by integrating multiple switches on a single semi-conductive substrate according to a desired power conversion topology, in a manner designed to reduce loop inductance.

### BRIEF DESCRIPTION OF THE DRAWINGS

These and other features, aspects, and advantages of the present disclosure will become better understood with regard to the following description, claims, and drawings. The present disclosure is illustrated by way of example, and not limited by, the accompanying figures. In the drawings, like numerals reference similar elements.

FIG. 1A and FIG. 1B show an integrated switch arrangement according to one or more aspects of the disclosure herein.

FIG. 2 shows an integrated switch arrangement according to one or more aspects of the disclosure herein.

FIG. 3 shows a buck converter utilizing an integrated switch arrangement according to one or more aspects of the disclosure herein.

### DETAILED DESCRIPTION

The accompanying drawings, which form a part hereof, show one or more examples of the disclosure. It is to be understood that the examples shown in the drawings and/or discussed herein are non-exclusive and that there are other examples of how the disclosure may be practiced.

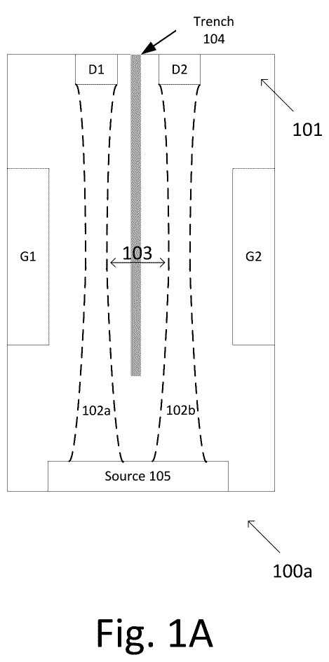

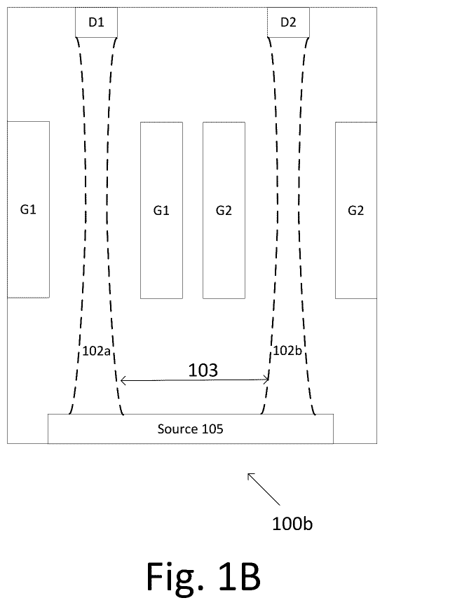

Reference is made to FIG. 1A, which depicts integrated switch 100a in accordance with an aspect of the disclosure herein. Integrated switch 100a may include a source 105 disposed on a semi-conductive substrate 101 (e.g., on a source location and/or contact), drains D1 and D2 disposed on the semi-conductive substrate 101 (e.g., on first and second drain locations and/or contacts), and gates G1 and G2 disposed on the semi-conductive substrate 101 (e.g., on first and second gate locations and/or contacts). The semi-conductive substrate 101 may be a negative type (N-type) substrate or a positive type (P-type) substrate. Channel 102a may be formed between source 105 and drain D1, and channel 102b may be formed between source 105 and drain D2. According to some aspects, channels 102a and 102b may be formed as depletion mode channels. For example, when no voltage is applied between G1 and source 105, channel 102a may conduct, and when a voltage is applied between G1 and source 105, channel 102a may be depleted of charge carriers and no current may flow. For example, when no voltage is applied between G2 and source 105, channel 102b may conduct, and when a voltage is applied between G2 and source 105, channel 102b may be depleted of charge carriers and no current may flow.

Channels 102a and 102b may be disposed in close proximity to one another. For example, distance 103 between channels 102a and 102b may be less than 10 millimeters, 5 millimeters, 1 millimeter, or 0.1 millimeter. The close spatial proximity (e.g., less than a predetermined threshold length) may reduce a loop inductance formed when integrated switch 100a is used in a power circuit. A capacitance (not shown in the figure) may be formed by the spatial proximity (e.g., close spatial proximity) between channels 102a and 102b.

In some aspects of the disclosure, a trench 104 may be formed between channel 102a and channel 102b. The trench may be formed at the close spatial proximity between the channels 102a and 102b. Therefore, the width of the trench 104 may be narrow and less than the distance 103 between channels 102a and 102b.

In some aspects of the disclosure, a controller may be configured to apply a first voltage signal to gate G1 and a second voltage signal to gate G2. The second voltage signal may be complementary to the first voltage signal. For example, the controller (e.g., gate-driver, microcontroller, field-programmable gate array (FPGA), etc.) may be configured to apply a first voltage signal characterized by a switching frequency having a duty cycle of D to gate G1 and a second voltage signal characterized by the switching frequency having a duty cycle of (1−D) to gate G2.

Reference is now made to FIG. 1B. Integrated switch 100b is similar to integrated switch 100a but does not include a trench. In integrated switch 100b, two gates (e.g., contacts of gates) of the same type may be placed on either side of each channel. For example, two G1 gates (e.g., contacts of G1 gates), connected in parallel, may be placed on both sides of channel 102a (e.g., a first G1 gate contact on the left side of channel 102a and a second G1 gate contact on the right side of channel 102a) and two G2 gates (e.g., contacts of G2 gates), connected in parallel, may be placed on both sides of channel 102b (e.g., a first G2 gate contact on the left side of channel 102b and a second G2 gate contact on the right side of channel 102b). A contact may be also referred to as an electrode.

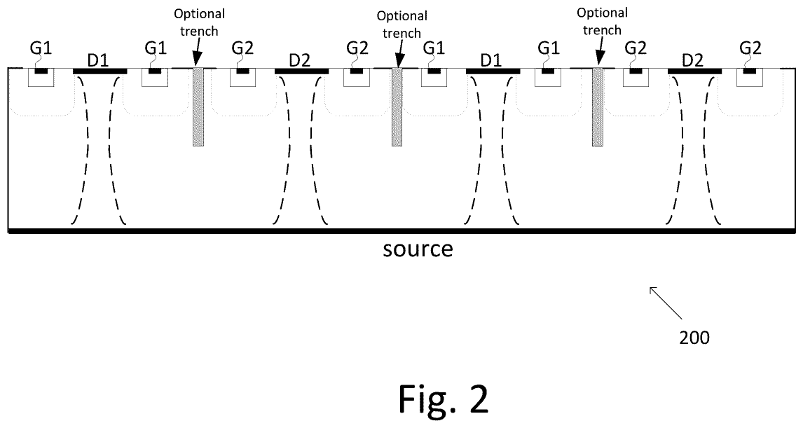

Reference is now made to FIG. 2, which depicts integrated switch 200 in accordance with aspects of the disclosure herein. Integrated switch 200 may be similar to integrated switches 100a and 100b (e.g., with channels as depletion mode channels), but with additional gates (e.g., contacts of gates) (collectively, G1 in FIG. 2) connected in parallel to first gate G1 of FIG. 1A, additional drains (e.g., contacts of drains) (collectively, D1 in FIG. 2) connected in parallel to drain D1 of FIG. 1A, and additional channels between each gate and drain. The same may hold for additional second gates, drains and channels. For example, additional gates (e.g., contacts of gates) (collectively, G2 in FIG. 2) may be connected in parallel to second gate G2 of FIG. 1A, additional drains (e.g., contacts of drains) (collectively, D2 in FIG. 2) may be connected in parallel to drain D2 of FIG. 1A, and additional channels may be formed between each gate and drain. Increasing the numbers of parallel-connected gates and drains and providing corresponding channels may reduce a resistance of the integrated switch and may further reduce loop inductance by spatially interleaving the currents flowing in each channel. The gate-channel-drain cells may be vertically stacked. In some aspects of the disclosure, a trench (e.g., an optional trench) may be formed between at least one pair of adjacent channels (e.g., channel 102a and channel 102b of FIG. 1A). The trench may be formed between the gates (e.g., contacts of gates, such as first gate G1 and second gate G2). The source may be common to all the additional channels between each gate and drain.

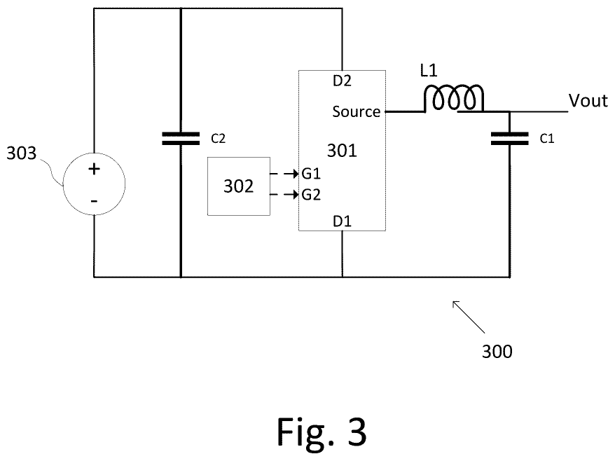

Reference is now made to FIG. 3, which shows an example for integrated switch 301 used as part of a power converter 300. Integrated switch 301 may comprise one or more of integrated switches 100a, 100b, and 200 of FIGS. 1A, 1B, and 2, respectively. Power converter 300 may be a buck converter utilizing integrated switch 301 as a half-bridge stage of the buck converter. Integrated switch 301 may be the same as or similar to one or more of integrated switches 100a, 100b, and 200. Terminals of drains D1 and D2 may be connected across direct current (DC) voltage terminals of power source 303. A source terminal may be connected to inductor L1, and a voltage Vout may be provided at a connection point between inductor L1 and capacitor C1. Controller 302 may provide signals to terminals respectively connected to gates G1 and G2 of integrated switch 301. When a voltage (e.g., a voltage above a threshold voltage) is applied to gate G1, channel(s) between first drain D1 and the source may be depleted of charge carriers, and current may flow between second drain D2 and the source. When a voltage (e.g., a voltage above a threshold voltage) is applied to gate G2, channel(s) between second drain D2 and the source may be depleted of charge carriers, and current may flow between first drain D1 and the source. Controller 302 may be configured to provide complementary signals to gates G1, G2. For example, controller 302 may provide a pulse-width modulation (PWM) signal having a duty cycle of 0.7 to gate G2, and a PWM signal having a duty cycle of 1−0.7=0.3 to gate G1, which may result in a voltage conversion ratio of 70% (e.g., since current flows between second drain D2 and the source 70% of the time). Controller 302 may comprise one or more digital and/or analog control circuits. Controller 302 may include, for example, one or more processors (e.g., a central processing unit (CPU), a microprocessor, an FPGA, etc.), memory (e.g., random access memory, read-only memory, flash memory, etc.), etc.

Integrated switches 100a, 100b, and/or 200 may be variously configured in different power topologies. For example, integrated switches 100a, 100b, and/or 200 may be used in buck converters, boost converters, buck-boost converters, full-bridge direct current/alternate current (DC/AC) or AC/DC converter, and the like.

All described features, and modifications of the described features, are usable in all aspects of the inventions taught herein. Furthermore, all of the features, and all of the modifications of the features, of all of the embodiments described herein, are combinable and interchangeable with one another

What is claimed is:

1. An integrated power switch comprising:
a semi-conductive substrate;
a source formed on the semi-conductive substrate;
a first drain formed on the semi-conductive substrate;
a first channel formed between the first drain and the source;
a first gate coupled to the first channel and configured to affect, based on a first voltage signal applied to the first gate, an amount of current flowing through the first channel;
a second drain formed on the semi-conductive substrate;
a second channel formed between the second drain and the source; and
a second gate coupled to the second channel and configured to affect, based on a second voltage signal applied to the second gate, an amount of current flowing through the second channel,
wherein the first channel and the second channel are between the first gate and the second gate, and
wherein the first channel and the second channel are arranged in spatial proximity, below a threshold distance, to one another.

2. The integrated power switch of claim 1, wherein the first gate comprises:
a first electrode of the first gate, wherein the first electrode of the first gate is disposed on a left side of the first channel; and
a second electrode of the first gate, wherein the second electrode of the first gate is connected in parallel to the first electrode of the first gate and disposed on a right side of the first channel,
wherein the second gate comprises:
a first electrode of the second gate, wherein the first electrode of the second gate is disposed on a left side of the second channel; and
a second electrode of the second gate, wherein the second electrode of the second gate is connected in parallel to the first electrode of the second gate and disposed on a right side of the second channel.

3. The integrated power switch of claim 1, further comprising a trench formed between the first channel and the second channel.

4. The integrated power switch of claim 1, wherein the first channel and the second channel are formed as depletion mode channels.

5. The integrated power switch of claim 1, wherein the semi-conductive substrate is one of an N-type substrate or a P-type substrate.

6. The integrated power switch of claim 1, wherein the threshold distance is one of 5 millimeters, 1 millimeter, or 0.1 millimeter.

7. An integrated power switch comprising:
a semi-conductive substrate;
a source formed on the semi-conductive substrate;
a plurality of first drains formed on the semi-conductive substrate, wherein the plurality of first drains are electrically coupled to each other in parallel;
a plurality of first channels, each first channel of the plurality of first channels being formed between a corresponding first drain, of the plurality of first drains, and the source;
a plurality of first gates, each first gate of the plurality of first gates being coupled to a corresponding first channel of the plurality of first channels, wherein each first gate of the plurality of first gates is configured to affect, based on a first voltage signal, an amount current flowing through the corresponding first channel;
a plurality of second drains formed on the semi-conductive substrate, wherein the plurality of second drains are electrically coupled to each other in parallel;
a plurality of second channels, each second channel of the plurality of second channels being formed between a corresponding second drain, of the plurality of second drains, and the source, wherein the plurality of first channels and the plurality of second channels are parallel to one another; and
a plurality of second gates, each second gate of the plurality of second gates being coupled to a corresponding second channel of the plurality of second channels, wherein each second gate of the plurality of second gates is configured to affect, based on a second voltage signal, an amount current flowing through the corresponding second channel,
wherein each adjacent pair of a first channel, of the plurality of first channels, and a second channel, of the plurality of second channels, are arranged in spatial proximity, below a threshold distance, to one another.

8. The integrated power switch of claim 7, wherein the plurality of first channels are arranged in an interleaved manner with respect to the plurality of second channels.

9. The integrated power switch of claim 7, wherein the threshold distance is one of 5 millimeters, 1 millimeter, or 0.1 millimeter.

10. The integrated power switch of claim 7, further comprising a plurality of trenches, each trench of the plurality of trenches being formed between a corresponding pair of a first channel, of the plurality of first channels, and a second channel, of the plurality of second channels.

11. The integrated power switch of claim 7, wherein the plurality of first channels and the plurality of second channels are formed as depletion mode channels.

12. The integrated power switch of claim 7, wherein the semi-conductive substrate is one of an N-type substrate or a P-type substrate.

13. An apparatus comprising:
a power source;
an integrated power switch comprising:
a semi-conductive substrate comprising a positive terminal and a negative terminal;
a source formed on the semi-conductive substrate, wherein the source is connected, via an inductor, to an output terminal;
a first drain formed on the semi-conductive substrate, wherein the first drain is connected to the negative terminal of the power source;
a first channel formed between the first drain and the source;
a first gate coupled to the first channel;
a second drain formed on the semi-conductive substrate, wherein the second drain is connected to the positive terminal of the power source;
a second channel formed between the second drain and the source; and
a second gate coupled to the second channel; and
a controller configured to:
apply a first voltage signal to the first gate and apply a second voltage signal to the second gate, wherein the second voltage signal is complementary to the first voltage signal,
wherein the first gate is configured to affect, based on the first voltage signal, an amount of current flowing through the first channel,
wherein the second gate is configured to affect, based on the second voltage signal, an amount of current flowing through the second channel,
wherein the first channel and the second channel are between the first gate and the second gate, and
wherein the first channel and the second channel are arranged in spatial proximity, below a threshold distance, to one another.

14. The apparatus of claim 13, wherein controller is configured to apply the first voltage signal having a duty cycle of D, and apply the second voltage signal having a duty cycle of 1-D.

15. The apparatus of claim 13, wherein the controller is further configured to control the integrated power switch as at least one of:
a half bridge,
a half-bridge part of a boost converter,
a part of a full-bridge converter, and
a half-bridge part of a buck converter.

16. The apparatus of claim 13, wherein the integrated power switch further comprises a trench formed between the first channel and the second channel.

17. The apparatus of claim 13, wherein the first channel and the second channel are formed as depletion mode channels.

18. The apparatus of claim 13, wherein the semi-conductive substrate is one of an N-type substrate or a P-type substrate.

19. The apparatus of claim 13, wherein the controller is further configured to cause one of:
based on applying no voltage between the first gate and the source, the first channel to conduct; or
based on applying a voltage between the first gate and the source, the first channel to be depleted of charge carriers.

20. The apparatus of claim 19, wherein, based on the first channel being depleted of the charge carriers, no current flows through the first channel.
